(19) United States
(12) Patent Application Publication
(10) Pub. No.: US 2012/0218028 A1
(43) Pub. Date: Aug. 30, 2012

(54) CAPACITIVE TOUCH PANEL, TOUCH SENSOR STRUCTURE AND A METHOD FOR MANUFACTURING THE CAPACITIVE TOUCH PANEL

(75) Inventors: CHUN-HSUEH CHU, Hsinchu City (TW); JUI-JUNG CHIU, Hsinchu County (TW)

(73) Assignee: TPK TOUCH SOLUTIONS INC., Taipei (TW)

(21) Appl. No.: 13/351,202

(22) Filed: Jan. 16, 2012

Related U.S. Application Data
(60) Provisional application No. 61/447,637, filed on Feb. 28, 2011.

(51) Int. Cl. H03K 17/96; H01H 11/00; H03K 17/975

(52) U.S. Cl. 327/517; 200/600; 29/622

(57) ABSTRACT

A capacitive touch panel comprises: a substrate and a touch sensor. The touch sensor is disposed on the substrate and includes a plurality of conductive elements, an input bus, and an output bus. The conductive elements are arranged to form a sensing matrix on same surface of the substrate. The input bus is electrically connected to one end of a first axis of the sensing matrix. The output bus is electrically connected to one end of a second axis of the sensing matrix. By this means, the present disclosure can achieve the purpose of simplifying the architecture of the capacitive touch panel.

This application claims the benefit of U.S. provisional application No. 61/447,637, filed on Feb. 28, 2011.

### BACKGROUND

1. Technical Field

The present disclosure relates to a touch panel. More particularly, the present disclosure relates to a capacitive touch panel, a touch sensor structure thereof, and a method for manufacturing the capacitive touch panel.

2. Description of the Related Art

In recent years, touch sensing technology has been widely used. For instance, in one application of touch sensing technology, touch input interface has gradually become a popular human-machine interface used by people to input information. Moreover, at present, a capacitive touch sensing technology is a mainstream for realizing multiple touch functions among various touch sensing technologies.

Architecture of a capacitive touch panel can mainly be classified into two modes. The first mode is shown as a schematic sectional view of a double-layer capacitive touch panel in accordance with conventional technology in FIG. 1. A plurality of first-axis (such as Y-axis) sensing electrodes 81 and a plurality of second-axis (such as X-axis) sensing electrodes 82 are formed respectively on both surfaces of a substrate 80. The first-axis sensing electrodes 81 and the second-axis sensing electrodes 82 are separated by the substrate 80, wherein the substrate 80 avoids intersection between the first-axis sensing electrodes 81 and the second-axis sensing electrodes 82. A touch point is determined by processing coupled charges between the first-axis sensing electrodes 81 and the second-axis sensing electrodes 82 before and after the capacitive touch panel is touched.

The second mode is shown as a schematic sectional view of a single-layer capacitive touch panel in accordance with conventional technology in FIG. 2. A plurality of first-axis (such as Y-axis) sensing electrodes (not shown) and a plurality of second-axis (such as X-axis) sensing electrodes 92 are formed on same surface of a substrate 90. Each first-axis sensing electrode comprises a plurality of first-axis conductive elements (not shown) and the adjacent first-axis conductive elements are connected by a first-axis wire 912. Similarly, each second-axis sensing electrode 92 comprises a plurality of second-axis conductive elements 921 and the adjacent second-axis conductive elements 921 are connected by a second-axis wire 922. Besides, an insulation material 93 is further disposed between each first-axis wire 912 and corresponding second-axis wire 922, wherein the second-axis wire 922 forms a jumper. The touch point is determined by processing the coupled charges between the first-axis sensing electrodes and the second-axis sensing electrodes 92 before and after the capacitive touch panel is touched.

However, architectures of the above conventional capacitive touch panels and corresponding manufacturing processes are complicated and therefore there exists a need for a new capacitive touch panel design, which is simple and more efficient.

### SUMMARY OF THE INVENTION

In order to solve the above technical problems, a touch sensor structure of a capacitive touch panel is improved in the present disclosure by making a single-layer plane sensing matrix on one surface of a substrate of a touch panel for obtaining signal variation on sensing axes of the sensing matrix.

According to one embodiment of the present disclosure, a capacitive touch panel comprises a substrate and a touch sensor with a plurality of conductive elements arranged to form a sensing matrix on same surface of the substrate to generate sense signal of a first axis and/or a second axis of the sensing matrix.

According to one embodiment of the present disclosure, a capacitive touch panel comprises: a substrate and a touch sensor. The touch sensor is disposed on the substrate and further includes a plurality of conductive elements, an input bus, and an output bus. The conductive elements are arranged to form a sensing matrix on same surface of the substrate. The input bus is electrically connected to one end of a first axis of the sensing matrix. The output bus is electrically connected to one end of a second axis of the sensing matrix.

According to another embodiment of the present disclosure, a touch sensor structure comprises: a plurality of conductive elements, an input bus and an output bus. The conductive elements are arranged to form a sensing matrix on one same plane. The input bus is electrically connected to one end of a first axis of the sensing matrix. The output bus is electrically connected to one end of a second axis of the sensing matrix.

According to another embodiment of the present disclosure, a method for manufacturing a capacitive touch panel comprises the steps of: forming a sensing matrix by arranging a plurality of conductive elements on a surface of a substrate; electrically connecting an input bus to one end of a first axis of the sensing matrix; and electrically connecting an output bus to one end of a second axis of the sensing matrix.

Therefore, effects that the present disclosure can achieve are not only simplifying the overall architecture of the touch panel to reduce manufacturing steps and accelerate production speed, but are also significantly reducing production cost and improving production yield.

The above summary and the following detailed description and drawings are made to further explain mode, means and effects adopted to achieve the present purpose of the disclosure. Other purposes and advantages of the present disclosure will be described in the subsequent description and drawings.

### BRIEF DESCRIPTION OF THE DRAWINGS

FIG. 1 is a schematic sectional view of a double-layer capacitive touch panel in accordance with conventional technology;

FIG. 2 is a schematic sectional view of a single-layer capacitive touch panel in accordance with conventional technology;

FIG. 3 is a schematic view of a capacitive touch panel in accordance with an embodiment of the present disclosure;

FIG. 4 is a schematic sectional view of the capacitive touch panel in accordance with the embodiment of the present disclosure;

FIG. 5 is an equivalent circuit view of a parasitic capacitor set of a touch sensor in accordance with the embodiment of the present disclosure;

FIG. 6 is a schematic view of signal variation of a touch sensor in accordance with an embodiment of the present disclosure;

FIG. 7 is a flowchart of a method for manufacturing a capacitive touch panel in accordance with a first embodiment of the present disclosure; and

FIG. 8 is a flowchart of a method for manufacturing a capacitive touch panel in accordance with a second embodiment of the present disclosure.

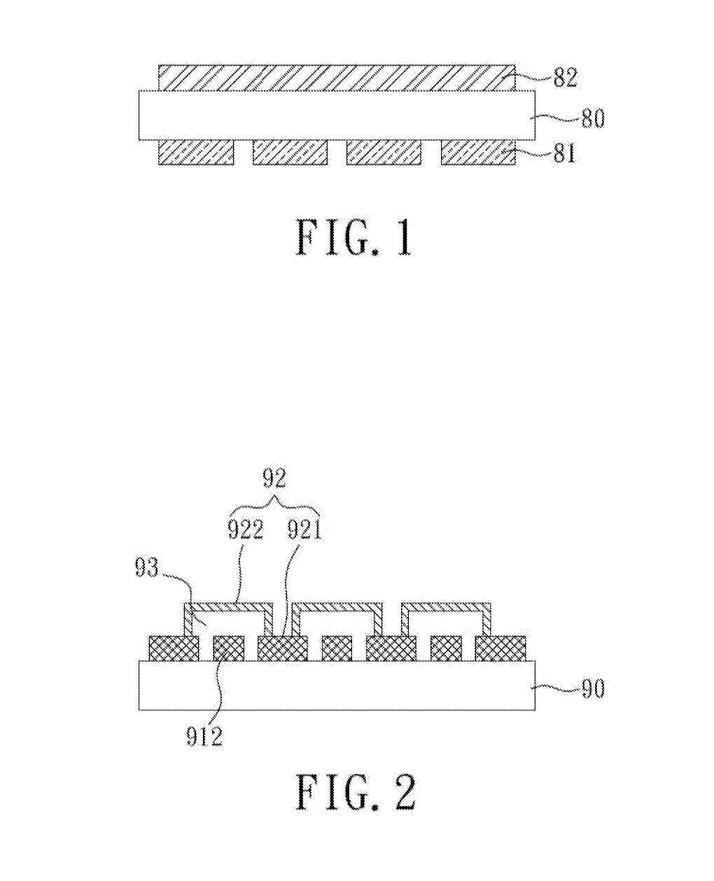

### DETAILED DESCRIPTION OF THE EMBODIMENTS

The present disclosure improves a touch sensor structure of a capacitive touch panel by directly making a single-layer plane sensing matrix on one surface of a substrate of a touch panel. In this way, signal variation on sensing axes of the sensing matrix are obtained directly through the designed single-layer plane sensing matrix and a touch point on the capacitive touch panel touched by a user can be detected in accordance with the present disclosure.

The touch sensor structure of the present disclosure can be applied to the following driving-sensing operations:
1. Driving single axis (such as X-axis) while sensing the other axis (such as Y-axis);
2. Driving single axis (such as X-axis) while sensing both different axes (X-axis and Y-axis);
3. Driving both different axes (X-axis and Y-axis) while sensing both different axes (X-axis and Y-axis).

In an embodiment, the first driving-sensing operation drives one axis of the sensing matrix and senses the other axis. In practical application, in order to detect location of the touch point more accurately, the second or the third driving-sensing operation can be adopted to detect location of the touch point by sensing two different axes. The following embodiments are described and explained based on the second driving-sensing operation.

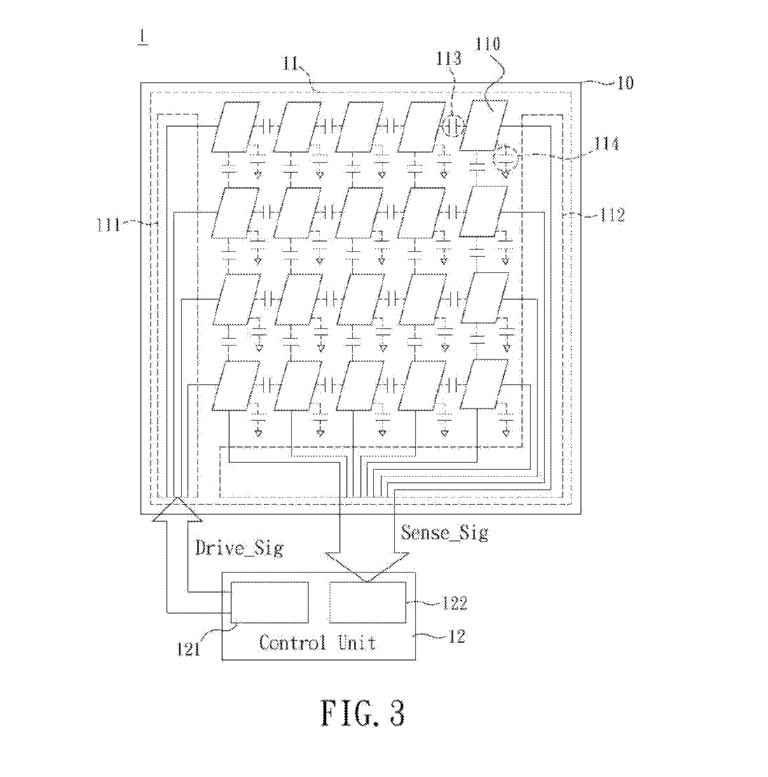

FIG. 3 illustrates a schematic view of a capacitive touch panel in accordance with an embodiment of the present disclosure. As depicted, the present embodiment provides a capacitive touch panel 1 comprising a substrate 10, a touch sensor 11, and a control unit 12. The substrate 10 works as a supporting base of the capacitive touch panel 1, and may be made of transparent materials such as glass or plastics.

The touch sensor 11 is disposed on the substrate 10. In practical design, the touch sensor 11 can be disposed on an upper surface or a lower surface of the substrate 10, which is not limited herein. Moreover, the “upper” and “lower” positions in the embodiment only represent a corresponding location relationship. For drawings of this specification, the upper surface of the substrate 10 is the one that is closer to the user while the lower surface is the one being farther from the user. In addition, the structure of the touch sensor 11 further comprises a plurality of conductive elements 110, an input bus 111, and an output bus 112.

The conductive elements 110 are arranged to form a sensing matrix on same surface of the substrate 10. According to electrical characteristics principle, a parasitic capacitor, which is a non-physical capacitor, can be formed between two general conductors. Thus, in the sensing matrix of the embodiment, each two adjacent conductive elements 110 induce a first parasitic capacitor 113 there between on a first axis and a second axis of the sensing matrix, which makes the original mutually independent conductive elements 110 form a connected reticular mode due to the effect of the first parasitic capacitor 113. On the other hand, each conductive element 110 will further induce a second parasitic capacitor 114 with the ground.

Besides, material of the conductive elements 110 can include Indium Tin Oxide (ITO), Indium Zinc Oxide (IZO), Gallium Zinc Oxide (GZO), Electroconductive Polymer, Carbon Nanotube-based Thin Films (CNT), ITO Nanoparticles, Nanowires, Mg(OH)₂: C, Graphene, or Zinc Oxide (ZnO). Moreover, shape of the conductive elements 110 of the present embodiment is designed as rhombic; and other shapes such as round, oval, polygonal, or cross can also be adopted. The material or the shape of the conductive elements 110 is not limited by the present disclosure.

The input bus 111 is electrically connected to one end of the first axis (such as X-axis) of the sensing matrix. The output bus 112 is electrically connected to the other end of the first axis of the sensing matrix and electrically connected to one end of the second axis (such as Y-axis) of the sensing matrix. Thus, the sensing matrix of the embodiment can be applied to the second driving-sensing operation. Referring to FIG. 3, the sensing matrix of the present embodiment is a simplified 5*4 matrix. In other words, the input bus 111 comprises four wire channels that are respectively electrically connected to one ends of four conductive element groups on the first axis formed by connection of the conductive elements 110. The output bus 112 comprises nine wire channels to be respectively electrically connected to the other ends of four conductive element groups on the first axis formed by connection of the conductive elements 110 and one ends of five conductive element groups on the second axis formed by connection of the conductive elements 110.

In other embodiments, the input bus 111 can also be further electrically connected to the other end of the second axis of the sensing matrix, which makes the sensing matrix apply to the third driving-sensing operation.

The control unit 12 is electrically connected to the input bus 111 and the output bus 112. The control unit 12 is used to generate a drive signal Drive_Sig to the input bus 111 and to receive at least one sense signal Sense_Sig transmitted by the output bus 112. More specifically, the control unit 12 comprises at least two multiplexers 121, 122. The multiplexer 121 is electrically connected to the input bus 111 to switch and output the drive signal Drive_Sig to different wire channels of the input bus 111 in sequence and the other multiplexer 122 is electrically connected to the output bus 112 to switch and receive the sense signal Sense_Sig transmitted by different wire channels of the output bus 112 in sequence.

FIG. 4 illustrates a schematic sectional view of the capacitive touch panel in accordance with the embodiment of the present disclosure. FIG. 4 further illustrates a stack relationship between the substrate 10 and the conductive elements 110. As shown in FIG. 4, the sensing matrix arranged and formed by the conductive elements 110 is directly disposed on the same plane of the upper surface of the substrate 10. Therefore, under the simplified architecture of the capacitive touch panel 1, the present embodiment can obtain signal variations on the first axis and the second axis through single-layer sensing matrix.

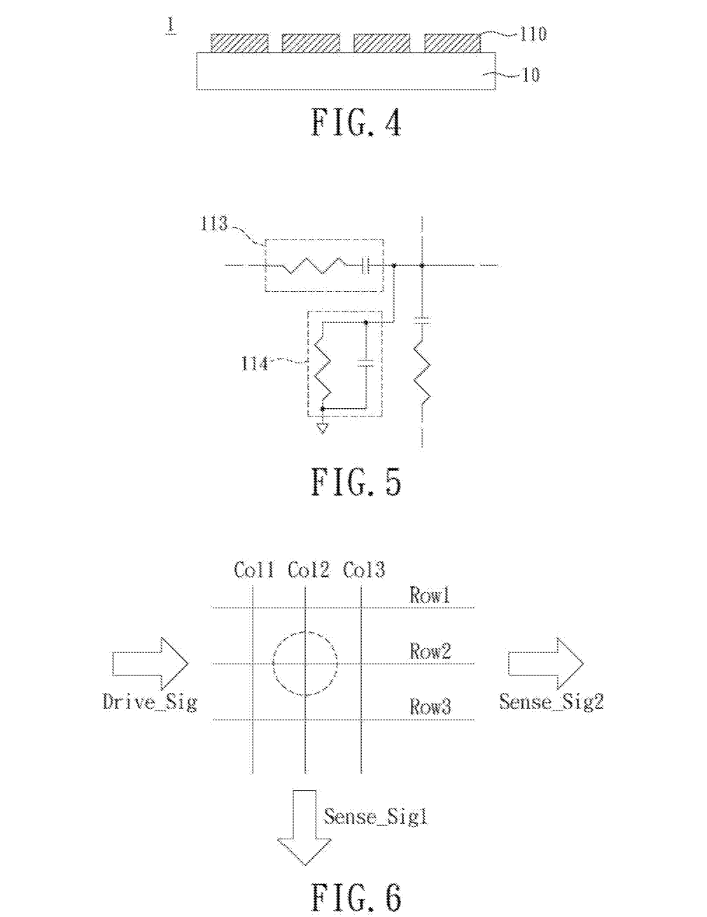

Next, in order to further illustrate operation of the touch sensor 11 in accordance with the present embodiment, please refer to FIG. 5 based on the architecture of FIG. 3. FIG. 5 shows an equivalent circuit of a parasitic capacitor set of the touch sensor in accordance with the embodiment of the present disclosure. As shown in FIG. 5, each first parasitic capacitor 113 formed in the sensing matrix is equivalent to a RC series circuit and each second parasitic capacitor 114 is equivalent to a RC parallel circuit.

In another embodiment, the control unit 12 generates the drive signal Drive_Sig of 10 MHz to the input bus 111 so that the touch sensor 11 operates under the working frequency of 10 MHz, wherein the frequency of the drive signal Drive_Sig determines penetration capability of the signal. It can be designed according to practical application without limitation.

In the condition that no touch point exists, the RC series circuit equivalent to the first parasitic capacitor 113 can be, for example, a resistor of 50 Ωserially connecting with a capacitor of 1 pF. The RC parallel circuit equivalent to the second parasitic capacitor 114 can be, for example, a resistor of 100MΩ parallelly connecting with a capacitor of 1 pF. When a user performs touch operation to generate at least one touch point, charges of the first parasitic capacitor 113 and the second parasitic capacitor 114 corresponding to the touch point and its surrounding area will be absorbed so that equivalent capacitance value reduces. In accordance with simulated data, the equivalent capacitance value of the first parasitic capacitor 113 and the second parasitic capacitor 114 corresponding to the touch point may reduce from 1 pF to 0.8 pF approximately. The farther the distance from the touch point, the lesser charges will be absorbed and the lower the extent of equivalent capacitance value reduction will be. It would be appreciated that the change of actual capacitance value can be subject to error due to the influence of environmental factors. According to what is mentioned above, at least one row and one column with maximum voltage variations can be obtained by detecting voltage change of all rows and columns of the sensing matrix before and after touching. Therefore, the touch point can be detected by calculating intersection of the row and the column with maximum variations.

FIG. 6 is a schematic view of signal variation of a touch sensor in accordance with an embodiment of the present disclosure. As depicted, one end of the sensing matrix on X-axis (row) in accordance with the present embodiment is used to receive the input of drive signal Drive_Sig. One end of the sensing matrix on Y-axis (column) and the other end of the sensing matrix on X-axis are used to output the sense signals Sense_Sig1 and Sense_Sig2 respectively. In addition, the embodiment illustrates the difference of signal variations on assumption of using a M*N sensing matrix with first sensing column Col1, second sensing column Col2, third sensing column Col3, first sensing row Row1, second sensing row Row2, and third sensing row Row3.

First of all, illustration will be made by comparing the sense signals Sense_Sig1 between different columns as shown in the following Table 1. The drive signal Drive_Sig of the embodiment enters the sensing matrix from the left side in FIG. 6 and based on the electric principle of signal attenuation, signal attenuation amounts of the first sensing column Col1, the second sensing column Col2, and the third sensing column Col3 get larger and larger. On the condition that touch point is not generated, the signal amounts measured are assumed to be: −32 dBm, −36 dBm and −41 dBm. When a certain touch point is generated, the signal amounts measured in the first sensing column Col1, the second sensing column Col2, and the third sensing column Col3 are respectively attenuated to: −33 dBm, −44 dBm and −44 dBm. Thereby, the signal variations (attenuation amounts) of the first sensing column Col1, the second sensing column Col2, and the third sensing column Col3 before and after the touch point is generated, can be obtained, wherein the signal variation of the second sensing column Col2 is the largest.

TABLE 1

| | | The second | |
|---|---|---|---|
| | The first sensing | sensing | The third sensing |
| | column (Col1) | column (Col2) | column (Col3) |
| Touch point not | −32 | −36 | −41 |
| generated | | | |
| Touch point | −33 | −44 | −44 |
| generated | | | |
| Signal variation | −1 | −8 | −3 |

Unit: dBm

On the other hand, illustration will be made by comparing the sense signals Sense_Sig2 between different rows. Similarly, the drive signal Drive_Sig enters the sensing matrix from the left side in FIG. 6; as shown in the following Table 2. Theoretically, the signal amounts measured in the first sensing row Row1, the second sensing row Row2, and the third sensing row Row3 will be the same on the condition that touch point is not generated, and herein the amount is −34 dBm. When touch point is generated; the signal amounts measured in the first sensing row Row1, the second sensing row Row2, and the third sensing row Row3 are assumed to be respectively attenuated to: −40 dBm, −45 dBm and −40 dBm. Thereby, the signal variations of the first sensing row Row1, the second sensing row Row2, and the third sensing row Row3 before and after the touch point is generated can be obtained, wherein the signal variation of the second sensing row Row2 is the largest.

TABLE 2

| | | The second | |
|---|---|---|---|
| | The first sensing | sensing | The third sensing |
| | row (Row1) | row (Row2) | row (Row3) |
| Touch point not | −34 | −34 | −34 |
| generated | | | |
| Touch point | −40 | −45 | −40 |
| generated | | | |
| Signal variation | −6 | −11 | −6 |

Unit: dBm

Therefore, with signal variations of all rows and columns obtained, location of the actual touch point (circled with dotted line in FIG. 6) can be detected by further calculating intersection of the second sensing column Col2 and the second sensing row Row2 with maximum variations.

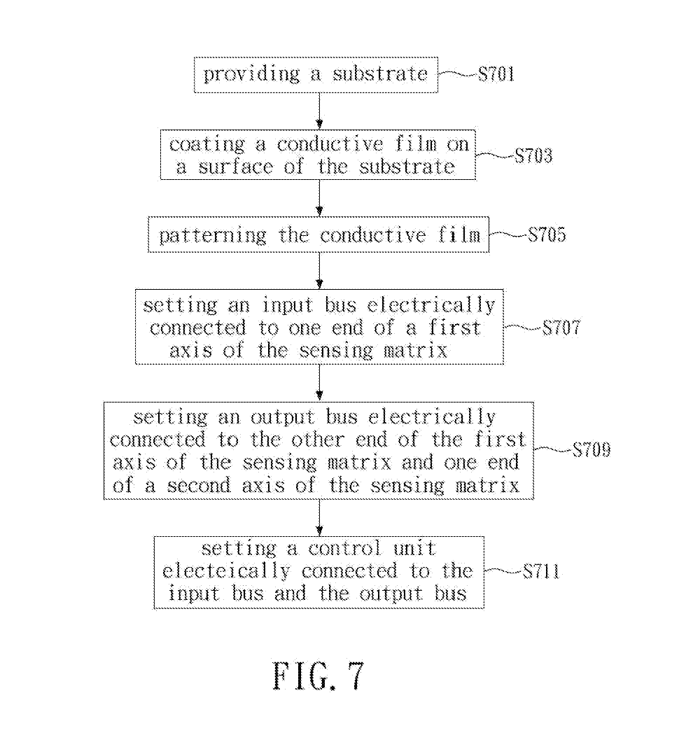

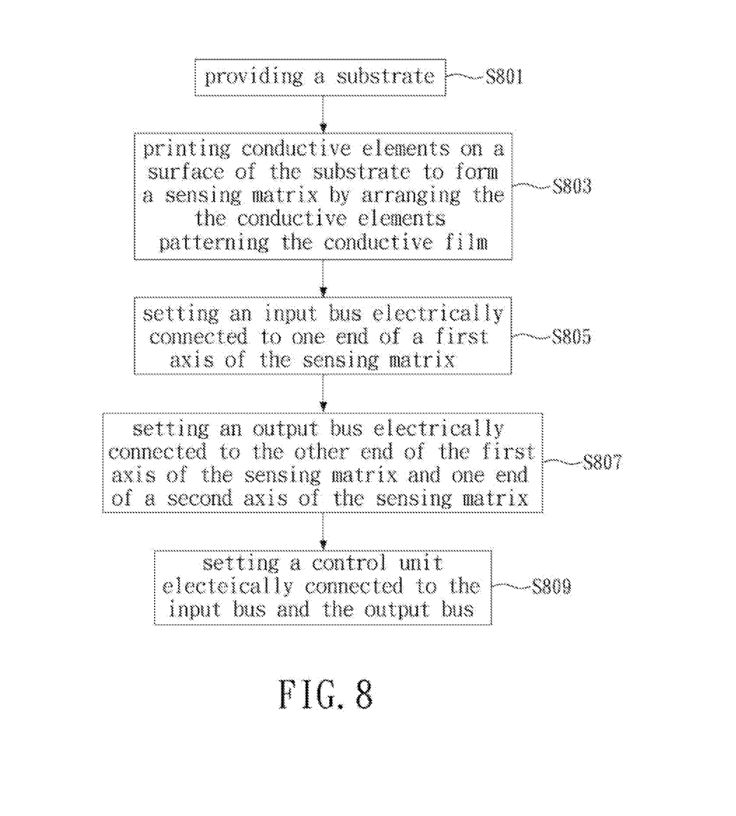

FIG. 7 is a flowchart of a method for manufacturing a capacitive touch panel in accordance with a first embodiment of the present disclosure. As depicted, a method for manufacturing the capacitive touch panel is provided in the present embodiment, comprising the steps of: providing a substrate (S701) used as a supporting base for the subsequent process; coating a conductive film on a surface of the substrate (S703), wherein coating on the upper surface or on the lower surface of the substrate can be determined according to actual design without limitation. The material of the conductive film can be, for example, selected from the group consisting of Indium Tin Oxide (ITO), Indium Zinc Oxide (IZO), Gallium Zinc Oxide (GZO), Electroconductive Polymer, Carbon Nanotube-based Thin Films (CNT), ITO Nanoparticles, Nanowires, Mg(OH)2: C, Graphene, or Zinc Oxide (ZnO).

Next, the method further comprises patterning the conductive film (S705) to form a sensing matrix by arranging a plurality of conductive elements. Those skilled in the art know that the process of patterning the conductive film approximately comprises baking, photomask alignment, exposing, developing and etching, etc. which is the so-called photo process, so no more details are described hereby. The present disclosure performs the patterning process on a single-layer conductive film once so as to achieve the architecture of the required sensing matrix.

Thereafter, the subsequent metal wiring process can be continued by setting an input bus electrically connected to one end of a first axis of the sensing matrix (S707), and setting an output bus electrically connected to the other end of the first axis of the sensing matrix and one end of a second axis of the sensing matrix (S709), wherein sequence of the steps (S707) and (S709) can be exchanged or adjusted in accordance with actual requirement of the process, which is not used to limit the present disclosure.

Incidentally, step (S703) to the step (S709) illustrate a procedure for making a touch sensor on a substrate.

Finally, the method further comprises setting a control unit electrically connected to the input bus and the output bus (S711), wherein the control unit can be made, for example, on a printed circuit board or a flexible circuit board and then electrically connected to the input bus and the output bus. Thereby, manufacturing of the capacitive touch panel in accordance with the embodiment can be finished.

FIG. 8 is a flowchart of a method for manufacturing a capacitive touch panel in accordance with a second embodiment of the present disclosure. The difference between the flowchart of the present embodiment and the flowchart of the first embodiment lies in that after providing a substrate (S801), the conductive elements are printed directly on a surface (upper surface or lower surface) of a substrate with a printing technology to form a sensing matrix by arranging conductive elements (S803) in accordance with the present embodiment. Thereby, the process required for the present embodiment is more simplified than that of the first embodiment.

The subsequent steps from (S805) to (S809) are metal wiring process steps for setting an input bus, an output bus, and a process for setting the control unit, and therefore no more details are described herein.

In conclusion, the present disclosure designs a plane matrix mode of a sensing matrix as an architecture of a touch sensor, which can not only effectively simplify the overall architecture of the touch panel to reduce manufacturing process and accelerate production speed, but can also reduce consumption of materials and complexity of manufacturing process so as to reduce production cost dramatically and promote production yield. Besides, the capacitive touch panel of the present disclosure can be simply integrated with various types of display screens in practical application.

Although the present disclosure has been described with reference to the embodiments thereof and best modes for carrying out the present disclosure, it is apparent to those skilled in the art that a variety of modifications and changes can be made without departing from the scope of the present disclosure, which is intended to be defined by the appended claims.

What is claimed is:

1. A capacitive touch panel, comprising:
a substrate and a touch sensor with a plurality of conductive elements arranged to form a sensing matrix on same surface of the substrate to generate sense signal of a first axis and/or a second axis of the sensing matrix.

2. The capacitive touch panel of claim 1, wherein adjacent conductive elements induce a first parasitic capacitor therebetween on the first axis and second axis of the sensing matrix, and each conductive element induces a second parasitic capacitor with ground.

3. The capacitive touch panel of claim 1, further comprising:
a control unit electrically connected to the touch sensor for generating a drive signal to the touch sensor and receiving a sense signal generated by the touch sensor.

4. A capacitive touch panel, comprising:
a substrate; and
a touch sensor disposed on the substrate, further comprising:
a plurality of conductive elements arranged to form a sensing matrix on same surface of the substrate;
an input bus electrically connected to one end of a first axis of the sensing matrix; and
an output bus electrically connected to one end of a second axis of the sensing matrix.

5. The capacitive touch panel of claim 4, further comprising:
a control unit electrically connected to the input bus and the output bus, generating a drive signal to the input bus and receiving a sense signal transmitted by the output bus.

6. The capacitive touch panel of claim 4, wherein the touch sensor is disposed on an upper surface or a lower surface of the substrate.

7. The capacitive touch panel of claim 4, wherein adjacent conductive elements induce a first parasitic capacitor therebetween on the first axis and second axis of the sensing matrix, and each conductive element induces a second parasitic capacitor with ground.

8. The capacitive touch panel of claim 4, wherein shape of the conductive elements is rhombic, round, oval, polygonal, or cross.

9. The capacitive touch panel of claim 4, wherein material of the conductive elements is selected from the group consisting of Indium Tin Oxide (ITO), Indium Zinc Oxide (IZO), Gallium Zinc Oxide (GZO), Electroconductive Polymer, Carbon Nanotube-based Thin Films (CNT), ITO Nanoparticles, Nanowires, Mg(OH)₂: C, Graphene, or Zinc Oxide (ZnO).

10. A touch sensor structure, comprising:
a plurality of conductive elements arranged to form a sensing matrix on same plane;
an input bus electrically connected to one end of a first axis of the sensing matrix; and
an output bus electrically connected to one end of a second axis of the sensing matrix.

11. The touch sensor structure of claim 10, wherein adjacent conductive elements induce a first parasitic capacitor therebetween on the first axis and second axis of the sensing matrix, and each conductive element induces a second parasitic capacitor with ground.

12. The touch sensor structure of claim 10, wherein shape of the conductive elements is rhombic, round, oval, polygonal, or cross.

13. The touch sensor structure of claim 10, wherein material of the conductive elements is selected from the group consisting of Indium Tin Oxide (ITO), Indium Zinc Oxide (IZO), Gallium Zinc Oxide (GZO), Electroconductive Polymer, Carbon Nanotube-based Thin Films (CNT), ITO Nanoparticles, Nanowires, Mg(OH)₂: C, Graphene, or Zinc Oxide (ZnO).

14. The touch sensor structure of claim 10, wherein the input bus receives a drive signal output by a control unit, and the output bus transmits a sense signal to the control unit.

15. A method for manufacturing a capacitive touch panel, comprising the steps of:
forming a sensing matrix by arranging a plurality of conductive elements on a surface of a substrate;
setting an input bus electrically connected to one end of a first axis of the sensing matrix; and
setting an output bus electrically connected to one end of a second axis of the sensing matrix.

16. The method for manufacturing capacitive touch panel of claim 15, further comprising:
setting a control unit electrically connected to the input bus and the output bus.

17. The method for manufacturing capacitive touch panel of claim 15, wherein the step of forming the sensing matrix further comprises:
coating a conductive film on the surface of the substrate; and
patterning the conductive film.

18. The method for manufacturing capacitive touch panel of claim 15, wherein the step of forming the sensing matrix comprises printing the conductive elements on the surface of the substrate with a printing technology.

19. The method for manufacturing capacitive touch panel of claim 15, wherein the sensing matrix is formed on an upper surface or a lower surface of the substrate.

20. The method for manufacturing capacitive touch panel of claim 15, wherein adjacent conductive elements induce a first parasitic capacitor therebetween on the first axis and second axis of the sensing matrix, and each conductive element induces a second parasitic capacitor with ground.
